(19) United States
(12) Patent Application Publication
(10) Pub. No.: US 2004/0124739 A1
(43) Pub. Date: Jul. 1, 2004

(54) APPARATUS AND METHOD OF GENERATING DIRECTIONAL ACOUSTIC WAVE

(76) Inventor: Xiao Dong Li, Beijing (CN)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,364

(22) Filed: Apr. 3, 2003

(30) Foreign Application Priority Data
Dec. 31, 2002 (TW) 91137971

(51) Int. Cl. H02N 2/00; H01L 41/04

(52) U.S. Cl. 310/311

(57) ABSTRACT

An apparatus and a method of generating a directional acoustic wave. The apparatus has a pre-compensator, an ultrasonic modulator, an amplitude modulator, an amplifier, and a directional ultrasonic beam emitter. The pre-compensator receives an audio signal to perform pre-compensation and then to generate a signal according to an ultrasonic air self-demodulation mechanism selected by a specific design. The ultrasonic modulator provides an ultrasonic carrier wave. The amplitude modulator receives the signal output by the pre-compensator and the ultrasonic carrier wave output by the ultrasonic modulator to load the signal into the ultrasonic carrier wave. The directional ultrasonic beam emitter is used to recover the audio signal by air self-demodulation. The directivity of the ultrasonic wave localizes the self-demodulation within the proceeding path of the wave beam, such that the audible sound carried by the carrier wave can only be heard locally to form the directional acoustic beam.

### CROSS REFERENCE TO RELATED APPLICATIONS

This application claims the priority benefit of Taiwan application serial no. 91137971, filed Dec. 31, 2002.

### BACKGROUND OF INVENTION

1. Field of the Invention

The invention relates in general to an ultrasonic technique, and more particularly, to an apparatus and a method for generating a directional acoustic wave to obtain directional sonic function. The apparatus and the method for generating a directional acoustic wave are applicable within a small space with a short extent.

2. Related Art of the Invention

Ultrasonic waves have been broadly applied to our daily lives. The application includes medical appliance, probe, and appliance for washing dead space of objects. However, as the bandwidth is beyond the audible range of human ears, ultrasonic waves do not directly provide an audio effect for human beings. However, by the advanced research of physics of ultrasonic wave carried by air, certain characteristics of the ultrasonic wave can be further utilized.

One of the important features of ultrasonic waves includes the significant directivity. This is why a bat can find a moth in the dark by sound location. Though ultrasonic waves belong to the non-audio wavelength, the audible acoustic wave (acoustic wave within 20 KHz) can be modulated into an ultrasonic wave to be clustered into a beam to be transmitted. During transmission, a non-linear interaction between the modulated wave and the atmosphere, also referred to as “self-demodulation”, is created to release an audible acoustic wave. Such a process allows for an audible acoustic wave to be transmitted in beams.

The above physical property has been implemented in a practical application. FIG. 1 shows a block diagram of a conventional apparatus for generating directional acoustic waves. In FIG. 1, the apparatus comprises a filter 100, an amplitude modulator 102, an ultrasonic modulator 108, an amplifier 104, and an ultrasonic generator 106.

The above filter 100 receives an audio signal to perform a normal filtering operation, and output the filtered signal. The ultrasonic generator 108 generates an ultrasonic carrier wave. The ultrasonic carrier wave generated by the ultrasonic generator 108 and the signal filtered by the filter 100 are input to the amplitude modulator 102. The filter signal is then modulated and loaded into the ultrasonic carrier wave by the amplitude modulator 102. The ultrasonic carrier wave containing the modulated signal audio is then amplified by the amplifier 104 and then input to the ultrasonic generator 106. The ultrasonic generator 106 can thus broadcast to a certain audience along the direction the ultrasonic carrier wave proceeds.

As mentioned above, the ultrasonic wave is self-demodulated with extreme non-linearity in air. Through a certain distance, the audio signal is demodulated from the ultrasonic carrier wave and becomes audible to human ears. To obtain higher directivity, more effective self-demodulation and longer transmission range, the ultrasonic generator 106 consists of multiple sound generating units 106a arranged in a specific array.

FIG. 2 shows an array of a plurality of sound generating units 106a. In FIG. 2, the sound generating units 106a are symmetrically arranged. The extreme non-linearity of the self-demodulation is typically the key consideration for arranging such an array.

Typically, the more the sound generating units 106a are used, the longer the transmission distance obtained, while the less the distortion is. The number of the sound generating units 106a is from tens to hundreds. As the self-demodulation is achieved in the medium of air, a certain distance is required to achieve sufficient demodulation level. That is, the conventional design is not suitable for use in a closed space with short extent. In addition, a large amount of the sound generating units 106a increases the volume and cost. Particularly for the consideration of convenience and cost, the number of the sound generating units 106a has to be reduced. Meanwhile, a tradeoff of the low distortion is required. For the short-distance users, the quality of sound reproduction is further seriously affected.

The short-distance application normally covers the range of 1 meter from the sound generating location to the listener. The ultrasonic waves continuously transmitted beyond such range will not be heard due to attenuation. The directivity of the ultrasonic wave allows the sound existent to be within a small closed space. However, due to the above factors, the conventional design has difficulty forming such a small closed sonic space. However, in the modern individuality and privacy-oriented life style, the small sonic space has been greatly demanded. With such small closed sonic space, the users in the same area will not be mutually interfered with. The great potential of future ultrasonic applications can thus be expected.

### SUMMARY OF INVENTION

The present invention provides an apparatus and a method for generating a directional acoustic wave which can be transmitted within a limited distance by using only one or a few, such as less than five, sound generating units. The sound generating units are either arranged in an array or a non-array disposition to achieve the effect of small closed sonic space.

The present invention further provides an apparatus and a method for generating a directional acoustic wave that enhances the self-demodulation effect of the ultrasonic wave in air. In addition to the applicability in short-distance closed space, the required number of sound generating units is reduced for long-distance transmission. The cost is thus reduced, and the design is simplified.

The apparatus for generating a directional acoustic wave provided by the present invention comprises a pre-compensator, an ultrasonic modulator, an amplitude modulator, a power amplifier, and a directional ultrasonic beam emitter. The pre-compensator receives an audio signal to perform pre-compensation thereon and to output a signal according to a specific ultrasonic air self-demodulation. The ultrasonic demodulator provides an ultrasonic wave carrier. The amplitude modulator receives the signal output by the pre-compensator and the ultrasonic carrier wave output by the ultrasonic modulator, and loads the signal into the ultrasonic carrier wave. The power amplifier receives an output of the amplitude modulator, and the directional ultrasonic beam emitter outputs to a listener the ultrasonic carrier wave that has been self-demodulated in air and recovered into the original audio signal.

The method of generating a directional acoustic wave provided by the present invention includes the following steps. According to a selected ultrasonic air self-demodulation mechanism, an audio signal is processed by pre-compensation to result in a compensated audio signal. The pre-compensated audio signal is loaded into an ultrasonic carrier wave which has a certain directivity. The ultrasonic carrier wave is amplified and then transmitted through air. By the selected ultrasonic air self-demodulation mechanism, the audio signal is recovered and audible to an audience.

### BRIEF DESCRIPTION OF DRAWINGS

These, as well as other features of the present invention, will become more apparent upon reference to the drawings wherein:

FIG. 1 shows a block diagram of a conventional apparatus for generating a directional acoustic wave;

FIG. 2 shows an array of sound generating units of the apparatus as shown in FIG. 1; and

FIG. 3 shows a block diagram of an apparatus for generating a directional acoustic wave provided in one embodiment of the present invention.

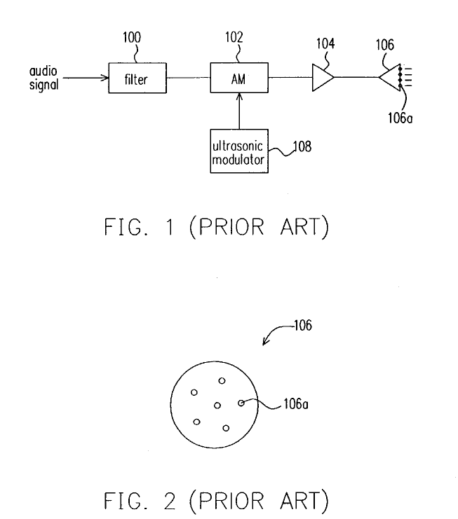

### DETAILED DESCRIPTION

The present invention is characterized in performing pre-compensation on an audio signal before the audio signal is modulated by amplitude and loaded into an ultrasonic carrier wave. Thereby, when the ultrasonic carrier wave is self-demodulated in air, the audio signal can be demodulated first. The design of the array of sound generating units can be simplified to use only one sound generating unit, while a small closed sonic space can be constructed.

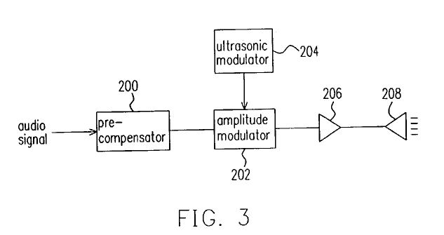

FIG. 3 shows a block diagram of an apparatus for generating a directional acoustic wave. In FIG. 3, the apparatus comprises a pre-compensator 200 to receive an audio signal, and perform pre-compensation on the audio signal according to a selected ultrasonic air self-demodulation mechanism. After pre-compensation, a signal is output by the pre-compensator 200. The audio signal can be an audio electric signal generated by an audio device or a normal audio signal. The audio electric signal includes a signal designed for outputting to a speaker. Some formats of the audio signal require additional signal conversion known to one skilled in the art. other words, the audio signal includes those audio signals that meet with the specification of the pre-compensator 200 which can enhance the air self-demodulation effect for the ultrasonic wave generated subsequently.

An ultrasonic modulator 204 is used to provide an ultrasonic carrier wave. An amplitude modulator 202 is used to receive the signal output by the pre-compensator 200 and the ultrasonic carrier wave output by the ultrasonic modulator 204, so as to load the signal into the ultrasonic carrier wave.

A power amplifier 206 is used to receive and amplify a signal output by the amplitude amplifier 204. A directional ultrasonic beam emitter 208 is used to emit the ultrasonic carrier wave to an audience (not shown), while the ultrasonic carrier wave has been self-demodulated in air and the audio signal recovered. The directional ultrasonic beam emitter 208 includes a single or a few ultrasonic generating devices, such as less than five ultrasonic generating devices arranged in an array. In the prior art, tens to hundreds of such ultrasonic generating devices are required. Moreover, while requiring a small sonic closed space, the directional ultrasonic beam emitter 208 includes a single sound generating device. In addition, the directivity range of the directional ultrasonic beam is no larger than about 30°, and the transmission range is no larger than 10 meters. While the design is oriented by high directivity or long-distance transmission, the distance can reache over 100 meters. In either condition, the pre-compensator 200 provides a significant effect.

The pre-compensator 200 further includes a filter function. By the pre-compensation of the pre-compensator 200, the directional ultrasonic beam emitter 208 provides sufficient self-demodulation within a short distance such as 1 meter, such that the audience can listen to the content of the audio signal. In this embodiment, the short distance includes a distance within 10 meters. Therefore, the pre-compensator 200 provides an effect unexpected by the prior art.

The present invention further provides a method of generating a directional acoustic wave. An audio signal is received. The audio signal is pre-compensated into a compensated audio signal according to a selected ultrasonic air self-demodulation mechanism. The compensated audio signal is loaded into an ultrasonic carrier wave. The ultrasonic carrier wave loaded with the compensated audio signal is then amplified and transmitted by air. As the ultrasonic carrier wave possesses a certain directivity, the audio signal can be demodulated from the ultrasonic carrier wave by the ultrasonic air self-demodulation mechanism and allowing the audience to hear the content thereof.

The application of the present invention includes:

1. Home appliances, office appliances and appliances used in amusement locations. Only the people located in the direction of the sound beam will sense the sound. This indicates that people can enjoy individual sound environments in the same place. The characteristics such as low driving power and simple structure allows the present invention to be applied to some portable or stationary apparatus such as personal data assistance (PDA), cellular phone, laptop computer or desktop computer.

2. Generation of a virtual sound source to achieve Hi-Fi surrounding sound effect in certain multimedia or other special locations requiring special sound effect.

3. Application of long-distance directional transmission in a noisy crowd or environment, and broadcast of an audio signal in a place such as a stadium, or a public location for directional broadcast and communication.

4. Application of confidential audio communication, allowing for a directional comment, telephone conversation and personal conversation.

Therefore, the present invention has a lot of advantages as follows.

1. High directivity. By the high directivity of ultrasonic energy conversion, an audio signal can be broadcast along a specific direction.

2. Short-distance transmission. As the signal is pre-compensated, the audio signal can be demodulated within a short distance to construct a closed sound space.

3. Convenience. The small space design without box structure and magnetic coils reduces the weight and volume.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

1. An apparatus for generating directional acoustic waves, comprising:
a pre-compensator, to receive an audio signal and perform pre-compensation thereon according to a selected ultrasonic air self-demodulation, and to output a signal;
an ultrasonic modulator, to provide an ultrasonic carrier wave;
an amplitude modulator, to receive the signal output by the pre-compensator and the ultrasonic carrier wave, and to load the signal into the ultrasonic carrier wave;
a power amplifier, to receive and amplify the ultrasonic carrier wave loaded with the signal; and
a directional ultrasonic beam emitter, to emit the ultrasonic carrier wave which has been self-demodulated by air and recover the audio signal to an audience.

2. The apparatus according to claim 1, wherein the directional ultrasonic beam emitter includes less than five sound generating units.

3. The apparatus according to claim 1, wherein the directional ultrasonic beam emitter has a directivity range of less than 30°.

4. The apparatus according to claim 1, wherein the pre-compensator comprises a filter function.

5. The apparatus according to claim 1, wherein the pre-compensator is operative to pre-compensate the audio signal to allow the directional ultrasonic beam emitter to provide sufficient demodulation of the ultrasonic carrier wave within a predetermined short distance, and allow an audience to hear content of the audio signal.

6. The apparatus according to claim 5, wherein the predetermined short distance is shorter than 10 meters.

7. The apparatus according to claim 1, wherein the directional ultrasonic beam emitter includes an array device.

8. The apparatus according to claim 1, wherein the audio signal includes an audio electric signal.

9. A method of generating a directional acoustic wave, comprising:
receiving an audio signal;
pre-compensating the audio signal into a compensated audio signal according to a selected ultrasonic air self-demodulation;
loading the compensated audio signal into an ultrasonic carrier wave with a specific directivity; and
transmitting the ultrasonic carrier wave loaded with the compensated audio signal to an audience at a predetermined distance via air, wherein the ultrasonic carrier wave has been self-demodulated by air allowing the audience to hear the content of the audio signal.

10. The method according to claim 9, wherein the predetermined distance is smaller than 10 meters.

11. The method according to claim 9, wherein the audio signal is so pre-compensated allowing the ultrasonic wave to be self-demodulated within 1 meter.

12. The method according to claim 9, wherein the directivity includes a range smaller than 30°.

13. The method according to claim 9, wherein the audio signal is pre-compensated according to the predetermined distance.

14. The method according to claim 9, wherein the step of receiving an audio signal includes receiving an audio electric signal.
